(19) United States
(12) Patent Application Publication
(10) Pub. No.: US 2025/0181798 A1
(43) Pub. Date: Jun. 5, 2025

(54) APPARATUS AND METHOD FOR DATA SYNCHRONIZATION BASED ON DIGITAL TWIN MODEL

(71) Applicant: Korea Electronics Technology Institute, Seongnam-si (KR)

(72) Inventor: Tai Gil KWON, Seongnam-si, Gyeonggi-do (KR)

(21) Appl. No.: 18/962,447

(22) Filed: Nov. 27, 2024

(30) Foreign Application Priority Data
Nov. 28, 2023 (KR) 10-2023-0168533
Nov. 26, 2024 (KR) 10-2024-0171099

(51) Int. Cl. G06F 30/20; G06F 9/445

(52) U.S. Cl. CPC G06F 30/20; G06F 9/44521

(57) ABSTRACT

Proposed are an apparatus and a method for data synchronization between an application based on a digital twin model and a physical world entity. The apparatus may include a digital twin module that generates a digital twin model modeling a physical world entity based on a control command of an application and synchronizes data between the application and the physical world entity through the digital twin model. The apparatus may also include a service interface that synchronizes control data for controlling the physical world entity of the application and sensing data sensed by the physical world entity between the application and the digital twin module through a first command protocol and a first event protocol. The apparatus may further include connectivity that synchronizes the control data and the sensing data between the digital twin module and the physical world entity through a second command protocol and a second event protocol.

### CROSS-REFERENCE TO RELATED APPLICATION

This application claims priority to and the benefit of Korean Patent Applications No. 10-2023-0168533 filed on Nov. 28, 2023, and No. 10-2024-0171099 filed on Nov. 26, 2024, the disclosures of each of which are incorporated herein by reference in their entirety.

### BACKGROUND

### Technical Field

The present specification relates to a technology for data synchronization between physical world entities and applications using a digital twin model.

### Description of Related Technology

There are various industrial fields in the physical world, and are many different systems composed of various sensors and actuators not only in different industrial fields but also in the same industrial field.

### SUMMARY

One aspect is a method for data synchronization between physical world entities and applications based on a digital twin module capable of providing independent interfaces and modeling-based sensing/control processing logic to various physical world entities.

Aspects of the present disclosure are not limited to the aspects disclosed herein. That is, other aspects that are not described may be obviously understood by those skilled in the art from the following description.

Another aspect is an apparatus for data synchronization based on a digital twin model. An apparatus for data synchronization based on a digital twin model includes: a digital twin module that generates a digital twin model modeling a physical world entity based on a control command of an application and synchronizes data between the application and the physical world entity through the digital twin model; a service interface that synchronizes control data for controlling the physical world entity of the application and sensing data sensed by the physical world entity between the application and the digital twin module through a first command protocol and a first event protocol; and connectivity that synchronizes the control data and the sensing data between the digital twin module and the physical world entity through a second command protocol and a second event protocol.

The apparatus for data synchronization based on a digital twin model and other embodiments may include the following features.

The digital twin model may be configured in a JavaScript Object Notation (JSON) format, but configured to include a digital model that digitally models the physical world entity and a resource path for accessing resources of the digital model, the digital model includes static data and variable data, the static data may include identification information of a physical entity and a static property information of the physical entity, and the variable data may include feature information of the physical object and dynamic property information of the physical object.

The first and second command protocols and the first and second event protocols may be configured as a data transmission protocol in the JSON format, the first command protocol may be configured to include a first command request protocol that transmits the control data including creation, retrieval, modification, and deletion commands for the resources of the digital twin model for controlling the physical world entity from the application to the digital twin model and a first command response protocol that notifies the application of a response result to the command request of the first command request protocol, the first event protocol may be a protocol that transmits a result of a status change of the resources of the digital twin model to the application, the second command protocol may be configured to include a second command request protocol that transmits the sensing data to the digital twin model to reflect a status change of the physical world from the physical world entity to the digital twin model and a second command response protocol that notifies the physical world entity of a response result to the command request of the second command request protocol, and the second event protocol may be a protocol that transmits a resource change event of the digital twin model for controlling the physical world entity to the physical world entity.

When the application requests the digital twin module to create the digital twin model through the first command request protocol, the digital twin model may be created by a process of causing the digital twin module to create the digital twin model and then respond to the application through the first command response protocol that the digital twin model is created and notify the physical world entity that the digital twin model is created through the second event protocol.

When the digital twin module receives a request from the application to modify a resource of the digital twin model associated with control of the physical world entity through the first command request protocol, the digital twin module may modify the digital twin model, and then notify the application that the digital twin model is modified through the first command response protocol and notify the physical world entity of a change in the resource of the digital twin model associated with the control of the physical world entity through the second event protocol to control the physical world entity, and when the physical world entity receives a request from the physical world entity to modify a resource of the digital twin model associated with the data sensed in the physical world entity through the second command request protocol, the digital twin module may modify the digital twin model, and then notify the physical world entity that the digital twin model is modified through the second command response protocol and notify the application of a change in the resource of the digital twin model associated with the data sensed in the physical world entity through the first event protocol to cause the application to retrieve the sensing data.

Another aspect is a method for data synchronization by the apparatus for data synchronization based on a digital twin model. The method for data synchronization by an apparatus for data synchronization based on a digital twin model includes: creating a digital twin model that models a physical world entity based on a control command of an application; modifying the digital twin model and then notifying the application that the digital twin model is modified through the first command protocol when a request for modification of a resource of the digital twin model associated with control of the physical world entity is received from the application through a first command protocol; notifying the physical world entity of a change in the resource of the digital twin model associated with the control of the physical world entity through a second event protocol to control the physical world entity; modifying the digital twin model and then notifying the physical world entity that the digital twin model is modified through the second command protocol when a request for modification of the resource of the digital twin model associated with the data sensed in the physical world entity is received from the physical world entity through a second command protocol; and notifying the application of the change in the resource of the digital twin model associated with the data sensed in the physical world entity through the first event protocol to cause the application to retrieve the sensing data.

The method for data synchronization by the apparatus for data synchronization based on a digital twin model and other embodiments may include the following features.

The digital twin model may be configured in a JavaScript Object Notation (JSON) format, but configured to include a digital model that digitally models the physical world entity and a resource path for accessing resources of the digital model, the digital model includes static data and variable data, the static data may include identification information of a physical entity and a static property information of the physical entity, and the variable data may include feature information of the physical object and dynamic property information of the physical object.

The first and second command protocols and the first and second event protocols may be configured as a data transmission protocol in the JSON format, the first command protocol may be configured to include a first command request protocol that transmits the control data including creation, retrieval, modification, and deletion commands for the resources of the digital twin model for controlling the physical world entity from the application to the digital twin model and a first command response protocol that notifies the application of a response result to the command request of the first command request protocol, the first event protocol may be a protocol that transmits a result of a status change of the resources of the digital twin model to the application, the second command protocol may be configured to include a second command request protocol that transmits the sensing data to the digital twin model to reflect a status change of the physical world from the physical world entity to the digital twin model and a second command response protocol that notifies the physical world entity of a response result to the command request of the second command request protocol, and the second event protocol may be a protocol that transmits a resource change event of the digital twin model for controlling the physical world entity to the physical world entity.

### BRIEF DESCRIPTION OF DRAWINGS

The following drawings attached to this specification illustrate preferred embodiments of the present disclosure, and serve to further understand the technical idea of the present disclosure along with the specific contents for performing the present disclosure. Therefore, the present disclosure should not be construed as limited to the matters shown in such drawings.

FIG. 1 is a diagram illustrating a method for data synchronization based on monitoring and control between a physical world system and an application.

FIG. 2 is a diagram illustrating a method for data synchronization between a physical world entity and an application based on a digital twin module by an apparatus for data synchronization based on a digital twin model according to an embodiment:

FIG. 3 is a diagram illustrating an example of a structure of a digital twin model provided by the digital twin module;

FIG. 4 is a diagram illustrating an example of a modeled model and a resource path according to an embodiment;

FIG. 5 is a diagram illustrating a command protocol of a service interface expressed in a JavaScript Object Notation (JSON) format;

FIG. 6 is a diagram illustrating an event protocol of a service interface expressed in the JSON format;

FIG. 7 is a diagram illustrating a command protocol of connectivity expressed in the JSON format;

FIG. 8 is a diagram illustrating an event protocol of the connectivity expressed in the JSON format;

FIG. 9 is a diagram illustrating an example of a model generation mechanism method according to an embodiment;

FIG. 10 is a diagram illustrating a process of controlling an actuator as an example of a data synchronization mechanism according to an embodiment; and

FIGS. 11A and 11B collectively show a diagram illustrating a process of sensing data as an example of a data synchronization mechanism according to an embodiment.

### DETAILED DESCRIPTION

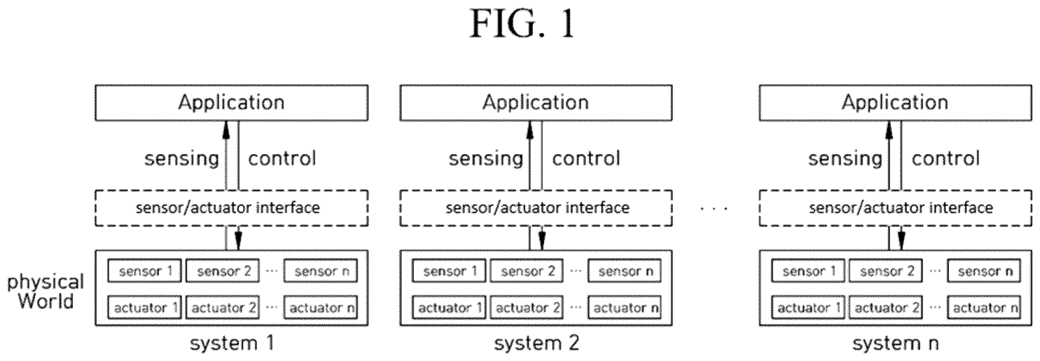

FIG. 1 illustrates a data synchronization method through monitoring and control between existing physical world systems (system 1, system 2, . . . , system n) and applications. According to the existing data synchronization method, each interface (sensor/actuator interfaces) for sensors and actuators needs to be configured according to specifications of the physical world system, and processing logic capable of sensing data or controlling the physical world system also needs to be directly implemented in applications according to specifications of a specific physical world system. The data synchronization method between the physical world system and the application has the problem of being very economically inefficient due to the occurrence of a lot of effort and cost.

It should be noted that the technical terms used in this specification are used only to describe specific embodiments and are not intended to limit the spirit of the technology disclosed in this specification. In addition, unless indicated otherwise in this specification, it is to be understood that all the technical terms used in this specification are construed as meaning as those that are generally understood by those who skilled in the art and as excessively comprehensive meanings and excessively reduced meanings. In addition, when the technical terms used in this specification are incorrect technical terms that do not accurately express the idea of the technology disclosed in this specification, it should be understood that the technology disclosed in this specification is replaced with technical terms that can be correctly understood by a person of ordinary skill in the art. Further, the general terms used in this specification should be understood according to the terms defined by the dictionary or the context and should not be excessively reduced meanings.

Embodiments of the present disclosure will be described in detail with reference to the accompanying drawings and the same or similar components are given the same reference numerals regardless of the numbers of figures and are not repeatedly described. In addition, the terms “module” and “unit” for components used in the following description are used only to easily make the disclosure. Therefore, these terms do not have meanings or roles that distinguish from each other in themselves. In addition, it should be understood that the accompanying drawings are provided only in order to allow exemplary embodiments of the present disclosure to be easily understood, and the spirit of the present disclosure is not limited by the accompanying drawings, but includes all the modifications, equivalents, and substitutions included in the spirit and the scope of the present disclosure.

Terms including an ordinal number such as first, second, or the like, used in this specification may be used to describe various components. However, these components are not limited to these terms. The terms are used to distinguish one component from another component. For example, the ‘first’ component may be named the ‘second’ component, and vice versa, without departing from the scope of the present disclosure.

It is to be understood that when one component is referred to as being “connected to” or “coupled to” another component, one component may be connected directly to or coupled directly to another component or be connected to or coupled to another component with the other component interposed therebetween. On the other hand, it is to be understood that when one component is referred to as being “connected directly to” or “coupled directly to” another component, it may be connected to or coupled to another component without the other component interposed therebetween.

Singular forms include plural forms unless the context clearly indicates otherwise.

It will be further understood that the terms “include” or “have” used in the present application specify the presence of features, numerals, steps, operations, components, parts mentioned in the present specification, or combinations thereof, but do not preclude the presence or addition of one or more other features, numerals, steps, operations, components, parts, or combinations thereof.

Hereinafter, embodiments according to the present disclosure will be described in detail with reference to the attached drawings.

### Data Synchronization Architecture Based on Digital Twin Model

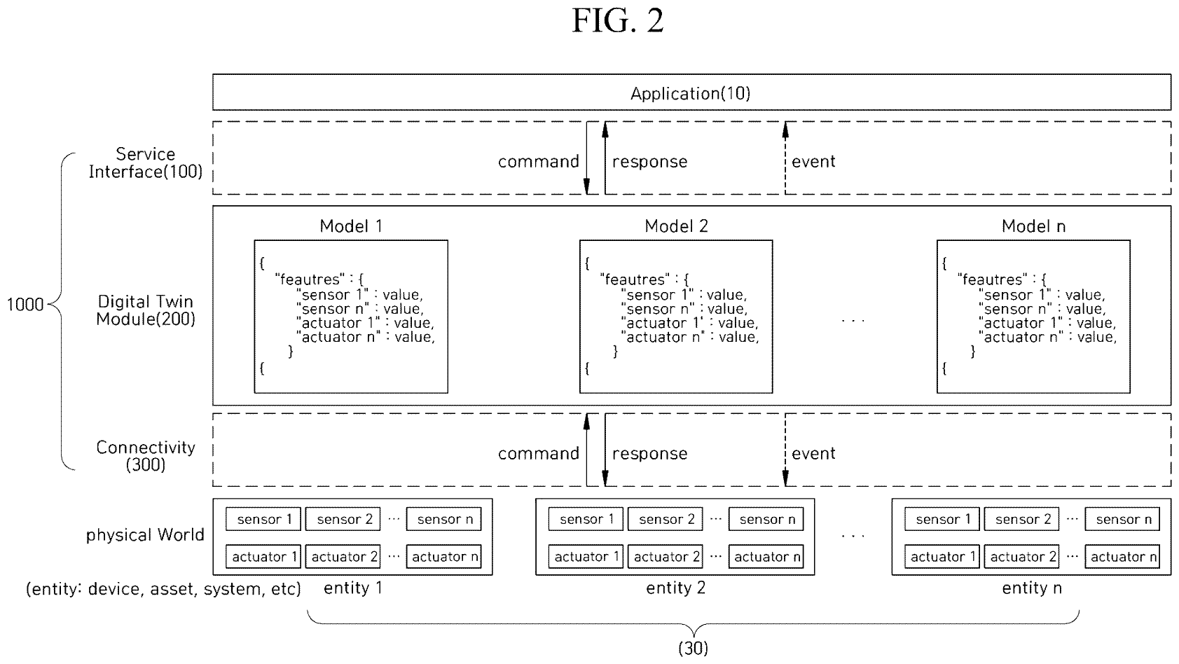

FIG. 2 is a diagram illustrating a method for data synchronization between a physical world entity and an application based on a digital twin module by an apparatus for data synchronization based on a digital twin model according to an embodiment.

Referring to FIG. 2, an apparatus 1000 for data synchronization based on a digital twin model includes a service interface 100, a digital twin module (or a digital twin processor) 200, and connectivity (or a synchronization processor) 300, and may perform data synchronization between a physical world entity 30 and an application 10 through the digital twin module.

The digital twin module 200 is logically located between the application 10 and physical world entities (entity 1, entity 2, . . . , entity n) 30. The digital twin module 200 is a common interface that enables data linkage between the application 10 and the physical world entity 30, and provides the service interface 100 and the connectivity 300, and digital twin models (model 1, model 2, . . . , model n) that enables dynamic modeling of control of various physical world entities and sensing of a physical world (environment) to which the physical world entities belong in the digital world, thereby supporting the data synchronization between the application 10 and the physical world entity 30. That is, the digital twin module 200 may generate the digital twin model that models the physical world entity 30 based on the control command of the application 10, and synchronize data between the application 10 and the physical world entity 30 through the digital twin model.

### Digital Twin Model

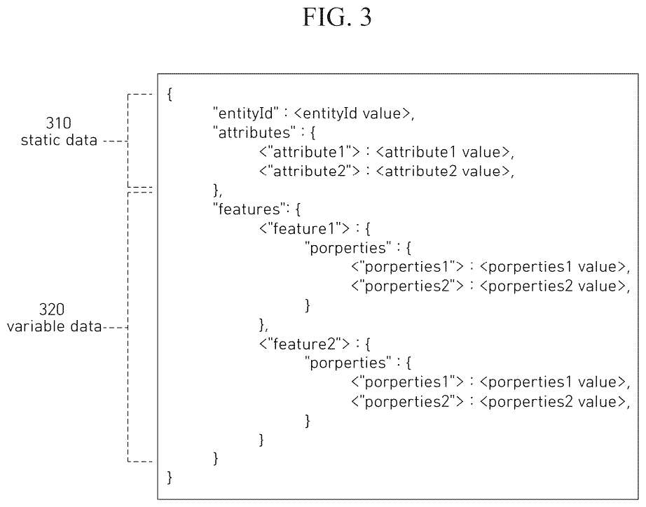

FIG. 3 illustrates an example of a structure of the digital twin model provided by the digital twin module.

Referring to FIG. 3, the digital twin module 200 according to an embodiment may provide a structure of the digital twin model configured in a JavaScript Object Notation (JSON) format. The meaning of each component key in the digital twin model structure will be described with reference to Table 1. In the digital twin model, entityId is a unique number for identifying an entity and is essential information for all entities, and attributes include unique information representing an entity such as a name, a role, and a location of the entity, and mean static data 310 that does not change easily once the attributes are set. The features are information representing features that the entity has, feature information may be distinguished through < “feature”>, and each feature includes properties. The properties include variable data 320 that easily changes in an entity, such as sensing data collected from the entity and control variables for controlling the entity.

TABLE 1

| Key | Description | Value | Type |
|---|---|---|---|
| entityId | unique identifier of entity | <entityId value> | string |
| attributes | static attribute group of entity | — | object |
| <“attribute”> | static attribute of entity | <attribute value> | object, string, integer, |
| | | | real number |
| features | group of features of entity | — | object |
| <“feature”> | feature identifier of entity | — | object |
| properties | group of dynamic properties of | — | object |
| | entity | | |
| <“property”> | dynamic property of entity | <property value> | object, string, integer, |
| | | | real number |

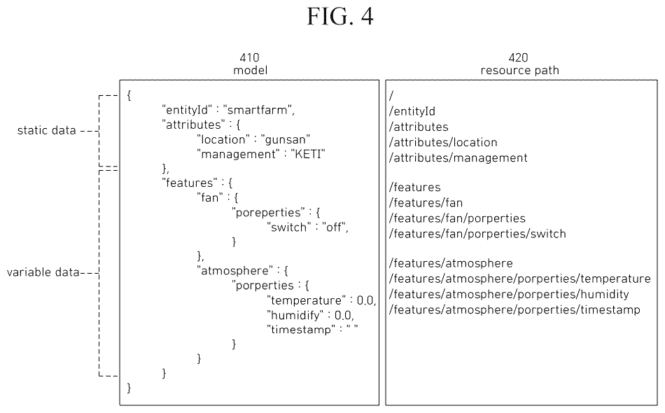

FIG. 4 is a diagram illustrating an example of a modeled model and a resource path according to an embodiment.

FIG. 4 illustrates shows an example of a model 410 modeled in the digital world by a digital twin module 200 according to the JSON format digital twin model structure of FIG. 3, and a resource path 420 for accessing resources of the model (410), targeting a smart farm composed of a ventilation fan actuator and a temperature and humidity sensor.

### Service Interface Between Digital Twin Module and Application

According to an embodiment, the service interface 100 is structured to enable mutual data linkage between the digital twin module 200 and the application 10 through a command protocol and an event protocol, as illustrated in FIG. 2, to synchronize control data for controlling the physical world entity 30 of the application 10 and the sensing data sensed by the physical world entity 30.

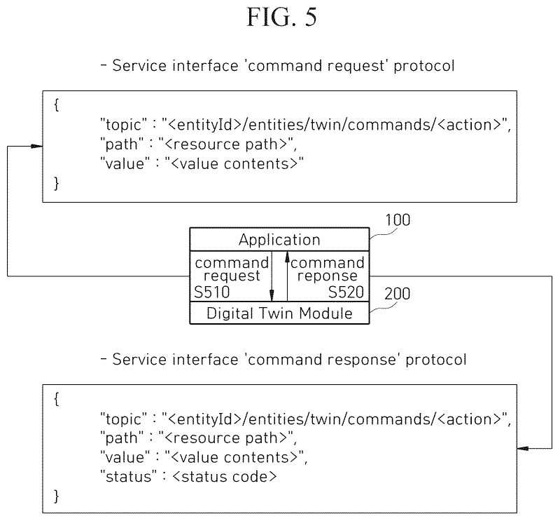

FIG. 5 is a diagram illustrating the command protocol of the service interface expressed in the JSON format.

Table 2 shows the meaning of each key of the command request protocol of the service interface 100 expressed in the JSON format, and Table 3 shows the meaning of each key of a command response protocol of the service interface 100 expressed in the JSON format.

Referring to FIG. 5, in this protocol, when the application 10 transmits a creation, retrieval, modification, and deletion command request for a model resource to the digital twin module 200 (S510), the digital twin module 200 operates by transmitting a command response to the request to the application 10 (S520). The command request protocol is composed of a topic defining a command target object and a purpose of the command, a path representing a path of a resource to be processed, and a value representing an actual value of a resource. The command response protocol, which is the processing result, composed of the topic, the path, and the value, just like the command request, and a status, which is a response code for the processing result, are further added.

TABLE 2

| | | | Value | | |
|---|---|---|---|---|---|
| Key | Description | Value | type | Value description | Type |
| topic | indicate | <entityId> | entity | indicate entityId of model | string |
| | command | | identifier | | |
| | target object | <action> | create | create resource | string |
| | and purpose of | | retrieve | retrieve resource | |
| | command | | modify | modify resource | |
| | | | delete | delete resource | |
| path | indicate | <resources | resource | divide and indicate | string |
| | resource path | path> | path | resource path to model | |
| | | | | by/ | |
| value | indicate | <value | resource | indicate actual value of | object, |
| | resource value | contents> | value | resource to be | String, |
| | | | | processed | integer, real |
| | | | | | number |

TABLE 3

| | | | Value | | |
|---|---|---|---|---|---|
| Key | Description | Value | type | Value description | Type |
| topic | indicate | <entityId> | entity | indicate entityId of model | string |
| | command | | identifier | | |
| | target object | <action> | create | create resource | string |
| | and purpose of | | retrieve | retrieve resource | |
| | command | | modify | modify resource | |
| | | | delete | delete resource | |
| path | indicate | <resource | resource | separately indicate | string |
| | resource path | path> | path | processed resource path | |
| | | | | by/ | |
| value | indicate | <value | processing | indicate processing | object, |
| | processing | contents> | result | result or actual value of | String, |
| | result for | | | processed resource | integer, real |
| | command | | | according to status | number |
| status | indicate | <status | 200 | normally retrieve | integer |
| | response code | code> | | resource | |
| | for processing | | 201 | normally create resource | |
| | result for | | 204 | normally modify or delete | |
| | command | | | resource | |
| | | | 400 | format of command | |
| | | | | request is incorrect | |
| | | | 401 | incorrect authentication | |
| | | | 403 | no permission to | |
| | | | | corresponding resource | |
| | | | 404 | no resource satisfying | |
| | | | | command request | |
| | | | 408 | response timeout | |
| | | | | (timeout) | |

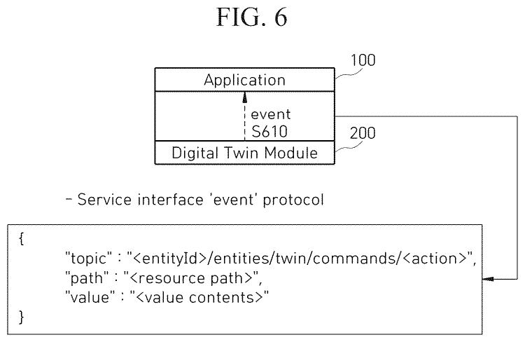

FIG. 6 is a diagram illustrating the event protocol of the service interface expressed in the JSON format.

Table 4 shows the meaning of each key of the event protocol of the service interface 100 expressed in the JSON format. Referring to FIG. 6, when the resource of the model changes, the digital twin module 200 transmits an event to the application 10 (S610). The event protocol is composed of the topic defining the command target object and the purpose of the command, the path representing the path of the resource to be processed, and the value representing the actual value of the resource.

TABLE 4

| | | | Value | | |
|---|---|---|---|---|---|
| Key | Description | Value | type | Value description | Type |
| topic | indicate | <entityId> | entity | indicate entityId | string |
| | command | | identifier | of model | |
| | target object | <action> | modified | resource is | string |
| | and purpose | | | modified | |
| | of command | | | | |
| path | indicate | <resource | resource | separately | string |
| | resource path | path> | path | indicate | |
| | | | | processed | |
| | | | | resource path by/ | |
| value | indicate | <value | resource | indicate actual | object, |
| | resource | contents> | value | value of | String, |
| | value | | | processed | integer, |
| | | | | resource | real |
| | | | | | number |

### Connectivity Between Digital Twin Module and Physical World

As illustrated in FIG. 2, the connectivity 300 according to an embodiment of the present disclosure is structured to enable the mutual data linkage between the digital twin module 200 and the physical world entity 30 to synchronize the control data and the sensing data between the digital twin module 200 and the physical world entity 30 through the command protocol and the event protocol.

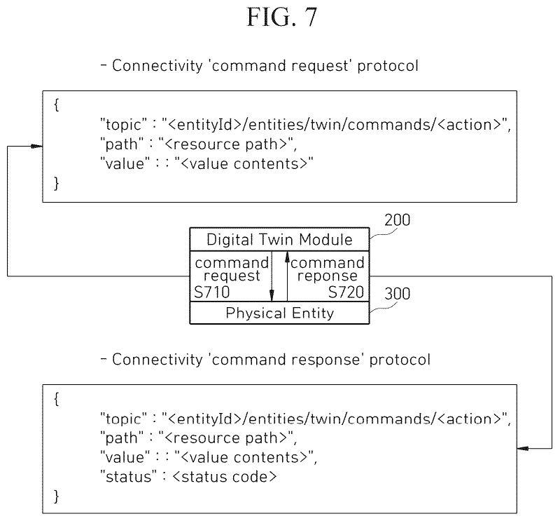

FIG. 7 is a diagram illustrating the command protocol of the connectivity expressed in the JSON format.

Table 5 shows the meaning of each key of the command request protocol of the connectivity 300 expressed in the JSON format, and Table 6 shows the meaning of each key of the command response protocol of the connectivity 300 expressed in the JSON format.

Referring to FIG. 7, in this protocol, when the command request for reflecting the status change that occurs in the physical world entity 30 is transmitted to the digital twin module 200 (S710), the digital twin module 200 operates by transmitting a command response to the command request to the physical world entity 30 (S720). The command request protocol is composed of the topic defining the command target object and the purpose of the command, the path representing the path of the resource to be processed, and the value representing the actual value of the resource. The command response protocol, which is the processing result, composed of the topic, the path, and the value, just like the command request, and the status, which is the response code for the processing result, are further added.

TABLE 5

| | | | Value | | |
|---|---|---|---|---|---|
| Key | Description | Value | type | Value description | Type |
| topic | indicate | <entityId> | entity | indicate entityId | string |
| | command | | identifier | of model | |
| | target object | <action> | modify | modify resource | string |
| | and purpose | | | | |
| | of command | | | | |
| path | indicate | <resource | resource | separately indicate | string |
| | resource | path> | path | resource path to | |
| | path | | | be processed by/ | |
| value | indicate | <value | resource | indicate actual | object, |
| | resource | contents> | value | value of resource | String, |
| | value | | | to be processed | integer, |
| | | | | | real |
| | | | | | number |

TABLE 6

| | | | Value | | |
|---|---|---|---|---|---|
| Key | Description | Value | type | Description | Type |
| topic | indicate | <entityId> | entity | indicate entityId of | string |
| | command | | identifier | model | |
| | target | <action> | modify | modify resource | string |
| | object and | | errors | error occurred while | |
| | purpose of | | | processing command | |
| | command | | | | |
| path | indicate | <resource | resource | separately indicate | string |
| | resource | path> | path | processed resource | |
| | path | | | path by/ | |
| | | | / | Indicate when error | |
| | | | | has occurred by/ | |
| value | indicate | <value | resource | define processing | string |
| | processing | contents> | value | result according | |
| | result for | | | to status | |
| | command | | error | when error occurs, | |
| | | | contents | define error contents | |
| | | | | according to status | |
| status | indicate | <status | 204 | indicate that | integer |
| | processing | code> | | resource has been | |
| | result for | | | successfully | |
| | command | | | modified | |
| | | | 400 | indicate that | |
| | | | | command is invalid | |

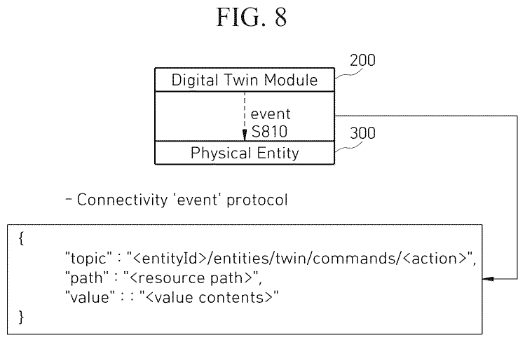

FIG. 8 is a diagram illustrating the event protocol of the connectivity expressed in the JSON format.

Table 7 shows the meaning of each key of the event protocol of the connectivity 300 expressed in the JSON format. Referring to FIG. 8, when the resource of the digital twin model changes, the digital twin module 200 transmits the resource change event of the model to the physical world entity 30 (S810). The event protocol is composed of the topic defining the command target object and the purpose of the command, the path representing the path of the resource to be processed, and the value representing the actual value of the resource.

TABLE 7

| | | | Value | | |
|---|---|---|---|---|---|
| Key | Description | Value | type | Description | Type |
| topic | indicate | <entityId> | entity | indicate entityId | string |
| | command | | identifier | of model | |
| | target | <action> | created | resource is created | string |
| | object and | | modified | resource is | |
| | purpose of | | deleted | modified | |
| | command | | | resource is deleted | |
| path | indicate | <resource | resource | separately indicate | string |
| | resource | path> | path | processed resource | |
| | path | | | path by/ | |
| value | indicate | <value | resource | indicate actual | object, |
| | resource | contents> | value | value of processed | String, |
| | value | | | resource | integer, |
| | | | | | real |
| | | | | | number |

### Model-Based Data Synchronization Mechanism

The data synchronization between the application 10 and the physical world entity 30 uses the digital twin model provided by the digital twin module 200 as an intermediary, and a synchronization mechanism for bidirectional data (control data and sensing data) operates. In order for this model-based operation mechanism to operate, the model modeled for the physical world entity 30 should first be defined.

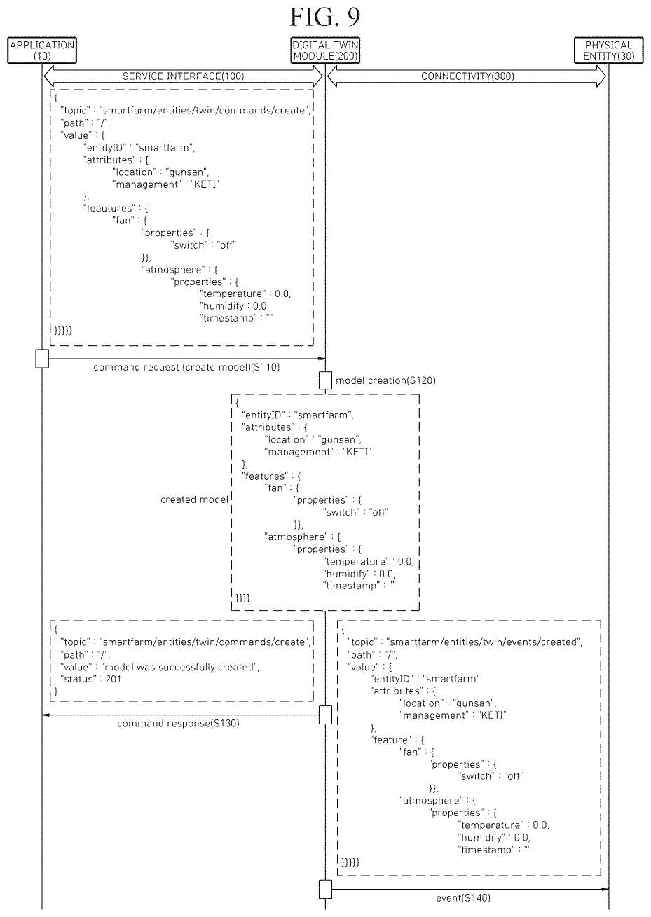

FIG. 9 is a diagram illustrating an example of a model generation mechanism method according to an embodiment.

FIG. 9 illustrates a generation mechanism of a digital twin model using the smart farm model composed of the ventilation fan actuator and the temperature and humidity sensor illustrated in FIG. 4 as an example. The model generation mechanism according to an embodiment operates in such a way that when the application 10 requests the digital twin module 200 to generate the model using the command of the service interface 100 (S110), the digital twin module 200 generates the model (S120), and then responds to the application 10 that the model has been generated through the command response (S130) and notifies the physical world entity 30 that the model has been generated through the event of the connectivity 300 (S140).

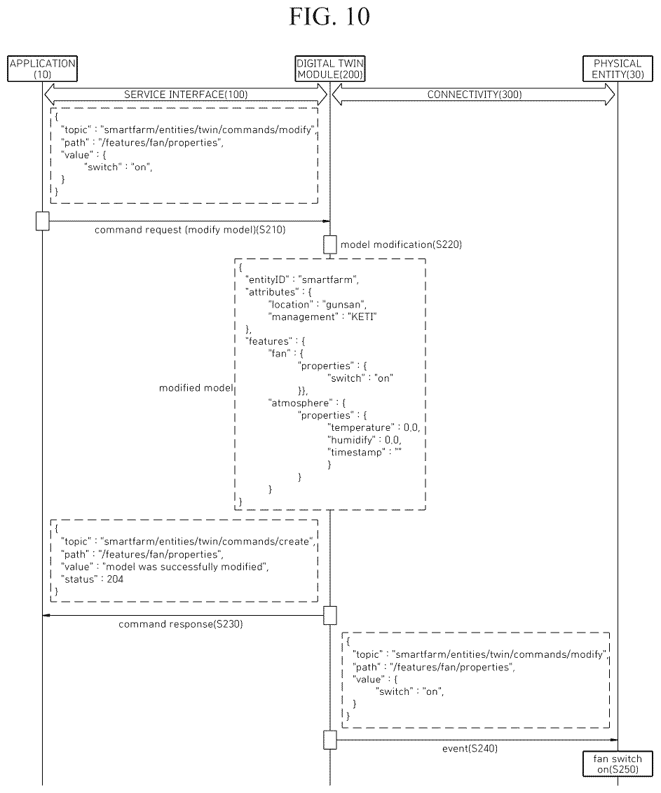

FIG. 10 is a diagram illustrating a process of controlling an actuator as an example of the data synchronization mechanism according to an embodiment.

FIG. 10 illustrates a data synchronization mechanism in an actuator control model generated in FIG. 9, taking actuator control as an example. Referring to FIG. 10, when a request is made to modify a model resource associated with ventilation fan control using the command of the service interface 100 in the application 10 (S210), the digital twin module 200 modifies the model (S220), notifies the application 10 that the model modification has been completed with a “status” response code through the command response of the service interface 100 (S230), and then notifies the physical world entity 30 of the changes in the model resource associated with the actuator control through the event of the connectivity 300 (S240), and finally, the physical world entity operates by driving the ventilation fan (fan switch on) (S250).

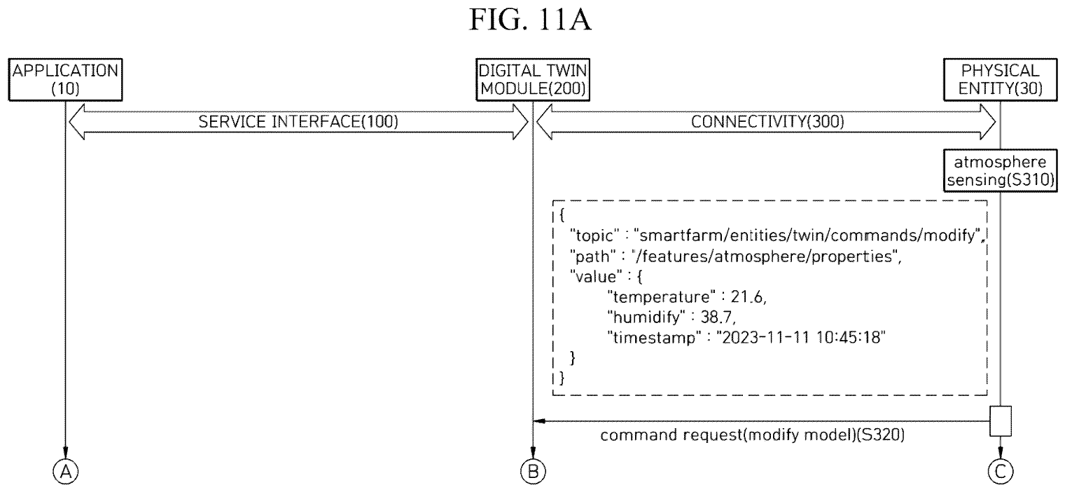

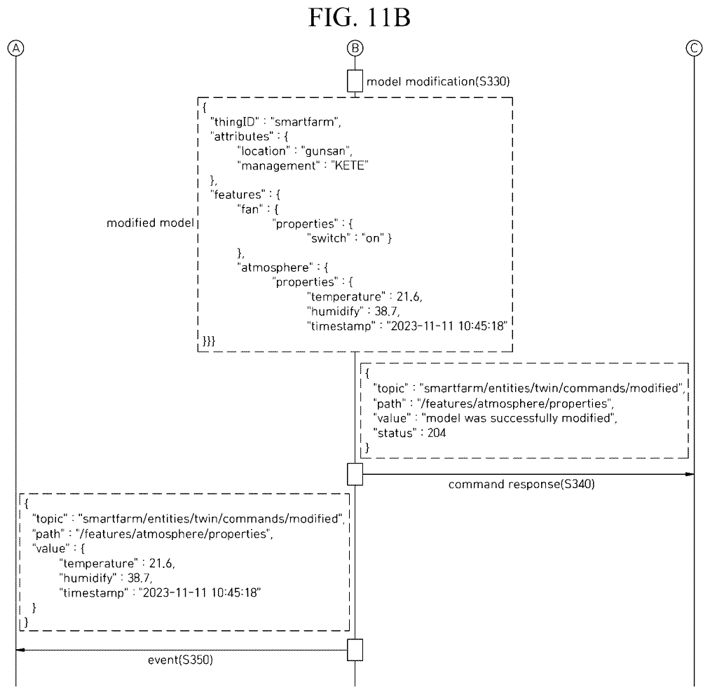

FIGS. 11A and 11B collectively show a diagram illustrating a process of sensing data as an example of a data synchronization mechanism according to an embodiment

Referring to FIGS. 11A and 11B, when new data is sensed from a sensor (S310), the physical world entity 30 requests to modify a model resource associated with sensing using the command of the connectivity 300 (S320). The digital twin module 200 modifies the generated control model in response to the command request (S330), and then notifies the physical world entity 30 that the model has been modified using the command response of the connectivity 300 (S340). Thereafter, the changes in the model resource associated with the sensing are notified to the application 10 through the event of the service interface 100 from the digital twin module 200 (S350), and finally, the application 10 operates by obtaining the sensing data.

In the embodiments described hereinabove, components and features of the present disclosure were combined with each other in a predetermined form. It is to be considered that the respective components or features are selective unless separately explicitly mentioned. The respective components or features may be implemented in a form in which they are not combined with other components or features. In addition, some components and/or features may be combined with each other to configure the embodiment of the present disclosure. A sequence of operations described in the embodiments of the present disclosure may be changed. Some components or features of any embodiment may be included in another embodiment or be replaced by corresponding components or features of another embodiment. It is obvious that claims that do not have an explicitly referred relationship in the claims may be combined with each other to configure an embodiment or be included in new claims by amendment after application.

Embodiments of the present disclosure may be implemented by various means, for example, hardware, firmware, software, or a combination thereof, etc. In the case in which an exemplary embodiment of the present disclosure is implemented by the hardware, it may be implemented by one or more application specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, or the like.

In the case in which an exemplary embodiment of the present disclosure is implemented by the firmware or the software, it may be implemented in a form of a module, a procedure, a function, or the like, performing the functions or the operations described above. A software code may be stored in a memory and be driven by a processor. The memory may be positioned inside or outside the processor and transmit and receive data to and from the processor by various well-known means.

It is obvious to those skilled in the art that the present disclosure may be embodied in another specific form without departing from the essential feature of the present disclosure. Therefore, the above-mentioned detailed description is to be interpreted as being illustrative rather than being restrictive in all aspects. The scope of the present disclosure is to be determined by reasonable interpretation of the claims, and all modifications within an equivalent range of the present disclosure fall in the scope of the present disclosure.

What is claimed is:

1. An apparatus for data synchronization based on a digital twin model, the apparatus comprising:
a digital twin processor configured to generate a digital twin model modeling a physical world entity based on a control command of an application and synchronize data between the application and the physical world entity through the digital twin model;
a service interface configured to synchronize control data for controlling the physical world entity of the application and sense data sensed by the physical world entity between the application and the digital twin module through a first command protocol and a first event protocol; and
a synchronization processor configured to synchronize the control data and the sensing data between the digital twin module and the physical world entity through a second command protocol and a second event protocol.

2. The apparatus of claim 1, wherein the digital twin model is configured in a JavaScript Object Notation (JSON) format, and includes a digital model configured to digitally model the physical world entity and a resource path for accessing resources of the digital model,
wherein the digital model includes static data and variable data,
wherein the static data includes identification information of a physical entity and a static property information of the physical entity, and
wherein the variable data includes feature information of the physical object and dynamic property information of the physical object.

3. The apparatus of claim 2, wherein the first and second command protocols and the first and second event protocols are configured as a data transmission protocol in the JSON format,
wherein the first command protocol is configured to include a first command request protocol that transmits the control data including creation, retrieval, modification, and deletion commands for the resources of the digital twin model for controlling the physical world entity from the application to the digital twin model and a first command response protocol that notifies the application of a response result to the command request of the first command request protocol,
wherein the first event protocol is configured to transmit a result of a status change of the resources of the digital twin model to the application,
wherein the second command protocol includes a second command request protocol configured to transmit the sensing data to the digital twin model to reflect a status change of the physical world from the physical world entity to the digital twin model and a second command response protocol configured to notify the physical world entity of a response result to the command request of the second command request protocol, and
wherein the second event protocol is configured to transmit a resource change event of the digital twin model for controlling the physical world entity to the physical world entity.

4. The apparatus of claim 3, wherein in response to the application requesting the digital twin module to create the digital twin model through the first command request protocol, the digital twin model is configured to be created by a process of causing the digital twin module to create the digital twin model and then respond to the application through the first command response protocol that the digital twin model is created and notify the physical world entity that the digital twin model is created through the second event protocol.

5. The apparatus of claim 4, wherein in response to the digital twin module receiving a request from the application to modify a resource of the digital twin model associated with control of the physical world entity through the first command request protocol, the digital twin module is configured to modify the digital twin model, and then notify the application that the digital twin model is modified through the first command response protocol and notify the physical world entity of a change in the resource of the digital twin model associated with the control of the physical world entity through the second event protocol to control the physical world entity, and
wherein in response to the physical world entity receiving a request from the physical world entity to modify a resource of the digital twin model associated with the data sensed in the physical world entity through the second command request protocol, the digital twin module is configured to modify the digital twin model, and then notify the physical world entity that the digital twin model is modified through the second command response protocol and notifies the application of a change in the resource of the digital twin model associated with the data sensed in the physical world entity through the first event protocol to cause the application to retrieve the sensing data.

6. A method for data synchronization by an apparatus for data synchronization based on a digital twin model, the method comprising:
creating a digital twin model that models a physical world entity based on a control command of an application;
modifying the digital twin model and then notifying the application that the digital twin model is modified through the first command protocol in response to a request for modification of a resource of the digital twin model associated with control of the physical world entity being received from the application through a first command protocol;
notifying the physical world entity of a change in the resource of the digital twin model associated with the control of the physical world entity through a second event protocol to control the physical world entity;
modifying the digital twin model and then notifying the physical world entity that the digital twin model is modified through the second command protocol in response to a request for modification of the resource of the digital twin model associated with the data sensed in the physical world entity being received from the physical world entity through a second command protocol; and
notifying the application of the change in the resource of the digital twin model associated with the data sensed in the physical world entity through the first event protocol to cause the application to retrieve the sensing data.

7. The method of claim 6, wherein the digital twin model is configured in a JavaScript Object Notation (JSON) format, and includes a digital model that digitally models the physical world entity and a resource path for accessing a resource of the digital model,
wherein the digital model includes static data and variable data,
wherein the static data includes identification information of a physical entity and a static property information of the physical entity, and
wherein the variable data includes feature information of the physical entity and dynamic property information of the physical entity.

8. The method of claim 7, wherein the first and second command protocols and the first and second event protocols are configured as a data transmission protocol in the JSON format,
wherein the first command protocol includes a first command request protocol that transmits the control data including creation, retrieval, modification, and deletion commands for the resources of the digital twin model for controlling the physical world entity from the application to the digital twin model and a first command response protocol that notifies the application of a response result to the command request of the first command request protocol,
wherein the first event protocol is configured to transmit a result of a status change of the resources of the digital twin model to the application,
wherein the second command protocol includes a second command request protocol that transmits the sensing data to the digital twin model to reflect a status change of the physical world from the physical world entity to the digital twin model and a second command response protocol that notifies the physical world entity of a response result to the command request of the second command request protocol, and
wherein the second event protocol is configured to transmit a resource change event of the digital twin model for controlling the physical world entity to the physical world entity.
